(19) United States
(12) Patent Application Publication
(10) Pub. No.: US 2017/0069345 A1
(43) Pub. Date: Mar. 9, 2017

(54) METHODS OF FORMING OVERCOATS ON MAGNETIC STORAGE MEDIA AND MAGNETIC STORAGE MEDIA FORMED THEREBY

(71) Applicant: Seagate Technology LLC, Cupertino, CA (US)

(72) Inventors: Michael J. Stirniman, Fremont, CA (US); Xiaoding Ma, Fremont, CA (US); Paul M. Jones, Palo Alto, CA (US); Hamid R. Samani, Los Altos, CA (US); Tommy T. Cheung, Alameda, CA (US); Christopher L. Platt, Fremont, CA (US); Qian Guo, Fremont, CA (US); Yang Yang, Fremont, CA (US)

(21) Appl. No.: 14/848,442

(22) Filed: Sep. 9, 2015

(51) Int. Cl. G11B 5/725; C23C 16/56; C23C 16/48; C23C 16/26; G11B 5/84; C23C 16/50

(52) U.S. Cl. CPC G11B 5/725; G11B 5/8408; C23C 16/50; C23C 16/482; C23C 16/26; C23C 16/56

(57) ABSTRACT

Methods of forming a magnetic storage disc, the method including depositing a carbon containing material on a magnetic recording layer to form a carbon containing layer, wherein the carbon containing layer is deposited using chemical vapor deposition, ion beam deposition, or filtered cathodic arc deposition; treating the carbon containing layer with a source of oxygen to form an oxygen layer; and depositing a lubricant on the oxygen layer.

### BACKGROUND

The reliability of the head-disk interface in magnetic storage media is provided by the combination of a protective overcoat and a lubricant layer. Increased durability and reliability of this two part system remains a need in the magnetic storage media industry.

### SUMMARY

Disclosed are methods of forming a magnetic storage disc, the method including depositing a carbon containing material on a magnetic recording layer to form a carbon containing layer, wherein the carbon containing layer is deposited using chemical vapor deposition, ion beam deposition, or filtered cathodic arc deposition; treating the carbon containing layer with a source of oxygen to form an oxygen layer; and depositing a lubricant on the oxygen layer.

Also disclosed are methods of forming a magnetic storage disc, the method including depositing a carbon containing material on a magnetic recording layer to form a carbon-containing layer, wherein the carbon-containing layer is deposited using chemical vapor deposition, ion beam deposition, or filtered cathodic arc deposition; forming an oxygen layer on the carbon-containing layer; and depositing a lubricant on the oxygen layer.

Also disclosed are articles that include a substrate; a magnetic recording layer; a protective carbon overcoat layer formed on the magnetic recording layer; an oxygen layer formed on the protective carbon overcoat layer; and a lubricant layer formed on the oxygen layer.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples can be used in various combinations. In each instance, the recited list serves only as a representative group and should not be interpreted as an exclusive list.

### BRIEF DESCRIPTION OF THE FIGURES

FIG. 1 is a pictorial representation of a data storage device in the form of a disc drive that can include a recording head constructed in accordance with an aspect of this disclosure.

FIG. 2 is a flowchart depicted disclosed illustrative methods.

FIG. 3 is a graph showing the lubricant bonding ratio and water contact angle (WCA) of structures.

FIG. 4 is a graph showing head burnishing (in Angstroms Å) of various magnetic media structures.

FIG. 5 is a graph showing the corrosion of various magnetic media as a function of overcoat thickness.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

The reliability of the head-disk interface in a hard disk drive relies on the durability and resistance to wear and corrosion of the magnetic storage media. The durability of the media is achieved almost primarily by the application of two protective layers, a carbon overcoat and a liquid lubricant film thereon. The carbon overcoat layer can be deposited on the surface of the disk using numerous methods, including for example direct current (DC) or radio frequency (RF) magnetron sputtering, plasma enhanced chemical vapor deposition (PECVD), ion beam deposition (IBD), or filtered cathodic arc (FCA) deposition methods.

Because of the ever increasing recording densities, the thickness of the carbon overcoat is approaching 20 Angstroms (Å). Such thin layers of carbon inherently limit the durability thereof. To achieve robust mechanical performance in such thin carbon overcoat layers, the interaction of the carbon overcoat with the lubricant must be maximized without decreasing the corrosion resistance of the film. Previously, the upper surface of the carbon overcoat was enriched with nitrogen in order to increase the interaction of the carbon and the lubricant. However, too much nitrogen in the carbon films degrades the mechanical properties of the carbon and decreases the corrosion resistance thereof. Therefore, there is a need for a method of modifying the carbon overcoat surface that will allow increased lubricant bonding while simultaneously maintaining or even increasing the corrosion resistance of the carbon overcoat.

Disclosed herein are methods that produce a carbon overcoat that has both advantageous interaction with the lubricant layer and desirable corrosion resistance.

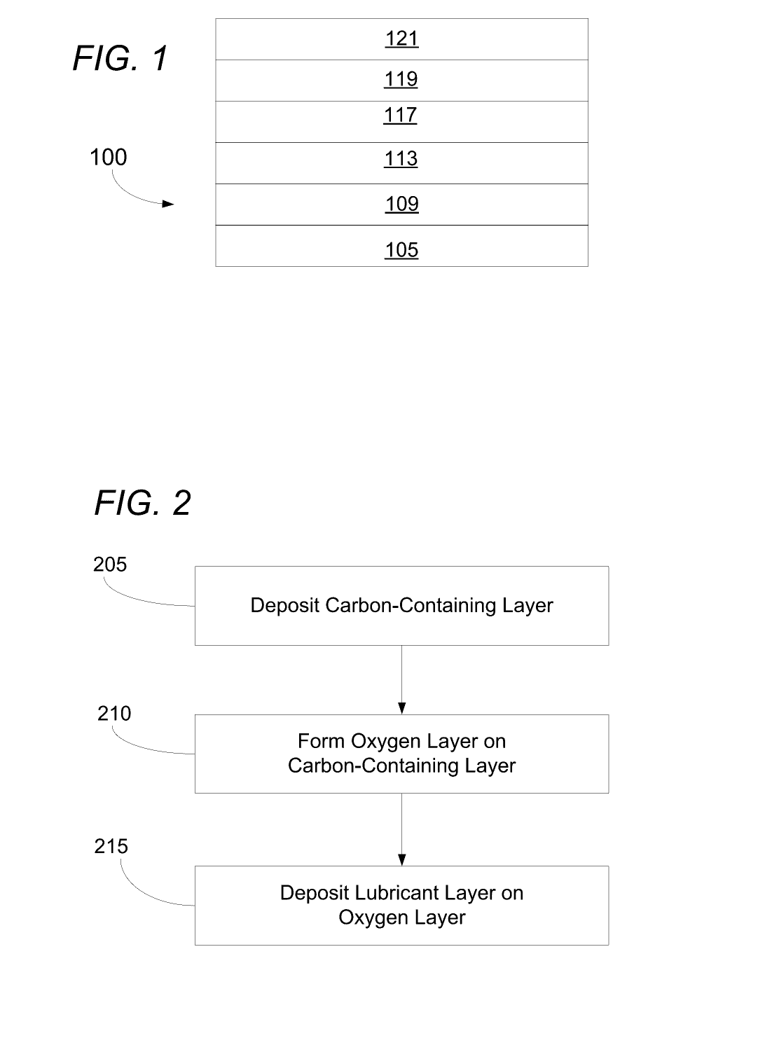

FIG. 1 is an illustration showing the layers of a disclosed magnetic media structure 100 including a substrate 105, a seed layer 109, a magnetic layer 113, a carbon containing layer 117, an oxygen layer 119 and a lube layer 121. The initial layer of the media structure is the substrate 105, which is typically made of nickel-phosphorous plated aluminum or glass that has been textured. The seed layer 109, typically made of chromium, is a thin film that is deposited onto the substrate 105 creating an interface of intermixed substrate 105 layer molecules and seed layer 109 molecules between the two. The magnetic layer 113, typically made of a magnetic alloy containing cobalt (Co), platinum (Pt) and chromium (Cr), is a thin film deposited on top of the seed layer 109 creating a second interface of intermixed seed layer 109 molecules and magnetic layer 113 molecules between the two. The carbon containing layer 117, including at least carbon, is a thin film that is deposited on top of the magnetic layer 113 creating a third interface of intermixed magnetic layer 113 molecules and carbon molecules between the two. On top of the carbon containing layer 117 is the oxygen layer 119. Finally the lube layer 121, typically made of a polymer containing carbon (C) and fluorine (F) and oxygen (O), is deposited on top of the oxygen layer 119. The durability and reliability of recording media is achieved primarily by the application of the carbon containing layer 117 and the lube layer 121. The combination of the carbon containing layer 117 and lube layer 121 can be referred to collectively as a protective overcoat.

The carbon containing layer 117 can be deposited on the magnetic layer 113 using conventional thin film deposition techniques such as ion beam deposition (IBD), chemical vapor deposition (CVD) or more specifically plasma enhanced chemical vapor deposition (PECVD). In some embodiments, the carbon containing layer is deposited using a method that is not a sputtering technique. The carbon containing layer 117 can include carbon and optionally one or more secondary materials. In some embodiments, a carbon containing layer 117 can include pure carbon (C), hydrogenated carbon (C:H), nitrogenated carbon (C:N), or a combination thereof (C:H:N) for example. In some embodiments, the carbon containing layer 117 can have a thickness of not greater than 30 Å or not greater than 20 Å. In some embodiments, the carbon containing layer 117 can have a thickness of not less than 20 Å, or not less than 17 Å.

Positioned on the carbon containing layer 117 is the oxygen layer 119. The oxygen layer is a layer or partial layer of oxygen molecules, atoms, or both. In some embodiments, the oxygen layer 119 can be at least a monolayer of oxygen atoms. In some embodiments, the oxygen layer includes oxygen atoms bound to underlying atoms of the carbon containing layer. In some embodiments the oxygen layer 119 can be at least a monolayer of oxygen atoms bound to atoms of the carbon containing layer 117.

The oxygen layer 119 can be formed by surface treating a previously formed carbon containing layer. Any treatment or process that can form at least a partial monolayer of oxygen (either atoms or molecules) on the carbon containing layer can be utilized to form the oxygen layer 119. In some embodiments, the surface of a carbon containing layer can be treated with UV energy, ozone, oxygen plasma, or combinations thereof. The working gas for the surface treatment can be an oxygen containing gas (e.g., air) or pure (substantially pure) oxygen (O₂). In some embodiments, the surface treatment can be carried out for not less than one (1) second or not less than 5 seconds for example. In some embodiments, the surface treatment can be carried out for not greater than 5 minutes for example.

On top of the oxygen layer 119 is the lubricant layer 121. A typical material used in lubricant layer 121 includes perfluoropolyethers (PFPEs), which are long chain polymers composed of repeat units of small perfluorinated aliphatic oxides such as perfluoroethylene oxide or perfluoropropylene oxide. PFPEs are used as lubricants because they provide excellent lubricity, wide liquid-phase temperature range, low vapor pressure, small temperature dependency of viscosity, high thermal stability, and low chemical reactivity. PFPEs also exhibit low surface tension, resistance to oxidation at high temperature, low toxicity, and moderately high solubility for oxygen. Several different PFPE polymers are available commercially, such as Fomblin Z (random copolymer of CF₂CF₂O and CF₂O units) and Y (random copolymer of CF(CF₃)CF₂O and CF₂O) including Z-DOL and AM 2001 from Montedison, Demnum (a homopolymer of CF₂CF₂CF₂O) from Daikin, and Krytox (homopolymer of CF(CF₃)CF₂O), for example.

Also disclosed herein are methods. FIG. 2 depicts illustrative methods. Methods 200 disclosed herein can start with step 205, depositing a carbon containing layer. The carbon-containing layer can have characteristics such as those discussed above. The carbon-containing layer can be deposited on the magnetic layer using thin film deposition techniques such as ion beam deposition (IBD), chemical vapor deposition (CVD) or more specifically plasma enhanced chemical vapor deposition (PECVD). In some embodiments, the carbon-containing layer is deposited using a method that is not a sputtering technique. In some embodiments, the carbon-containing layer can be deposited using chemical vapor deposition, for example plasma enhanced chemical vapor deposition. In some embodiments, non-sputtering techniques, for example chemical vapor deposition, can offer higher deposition rates, lower occurrence of deposition related defects (e.g., target spits from sputtering targets, etc.), or combinations thereof.

A next step in illustrative methods 200 can include step 210, forming an oxygen layer on the carbon-containing layer. The oxygen layer can have characteristics such as those discussed above. In some embodiments, the oxygen layer can be formed by surface treating a previously formed carbon containing layer. Any treatment or process that can form at least a partial monolayer of oxygen (either atoms or molecules) on the carbon-containing layer can be utilized to form the oxygen layer. In some embodiments, the surface of a carbon-containing layer can be treated with UV energy, ozone, oxygen plasma, or combinations thereof. In some embodiments, a carbon-containing layer can be treated with a combination of UV energy and ozone. The working gas for the surface treatment can be an oxygen containing gas (e.g., air) or pure (substantially pure) oxygen (O₂). In some embodiments, the surface treatment can be carried out for not less than one (1) second, not less than 5 seconds, not less than 90 seconds for example. In some embodiments, the surface treatment can be carried out for not greater than 5 minutes or not greater than 4 minutes for example.

In some embodiments, the surface treatment can be undertaken using an in-situ method where the process is integrated into a larger process of forming the media stack itself In some embodiments, ex-situ methods can be utilized, but may involve additional process steps and control methods. In some embodiments, methods of treating the carbon containing layer can result in a minimum of oxidation of the remaining (the “bulk”) carbon-containing layer or media stack oxidation. Specific conditions could include specific power and/or duration settings, for example.

A next step in illustrative methods 200 can include step 215, forming a lubricant layer on the oxygen layer. The lubricant layer can have characteristics such as those discussed above. In some embodiments, lubricant layer can be applied evenly, as a thin film, by dipping the discs in a bath containing a mixture of a few percent of PFPE in a solvent and gradually draining the mixture from the bath at a controlled rate. The solvent remaining on the disc evaporates and leaves behind a layer of lubricant having a thickness of not greater than 100 Å. In some embodiments, a lubricant layer can also be applied using an in-situ vapor deposition process that includes heating the PFPE with a heater in a vacuum tube process chamber.

### EXAMPLES

Carbon-containing layers including hydrogenated carbon (“CH”) and hybrid hydrogenated nitrogenated carbon as a comparative sample (“CHN”) films made by PECVD using substrate bias to control the energy of the impinging ions using a commercially available source technology were then treated with UV purged with clean dry air (CDA) for various lengths of time. The disk bias used provides ˜100V energy per carbon atom.

Then, a lubricant film was deposited on the surface either by dip coating in a dilute solution of nominal PFPE type lubricant or from a vacuum in which the temperature dependent vapor pressure of the PFPE-type lubricant transfers lubricant from a reservoir to the disk surface. The lubricant layers had thicknesses from about 0.5 nm to about 2.5 nm.

The samples were analyzed using ESCA. Table 1 shows the results

TABLE 1

| | Carbon- | UV/ozone | | | |
|---|---|---|---|---|---|
| | containing | time | | | |
| Sample No. | layer | (seconds) | ESCA (Å) | N/C | O/C |
| Comparative | i-CH/N+ | None | 23.8 | 0.12 | 0.20 |
| 1 | i-CH | 100 | 23.5 | <0.01 | 0.32 |
| 2 | i-CH | 200 | 23.1 | <0.01 | 0.39 |

The oxygen content at the surface is indicated by the oxygen/carbon (O/C) ratio from ESCA measurement. As seen from Table 1, as the UV/ozone treatment time is increased, the oxygen content increases.

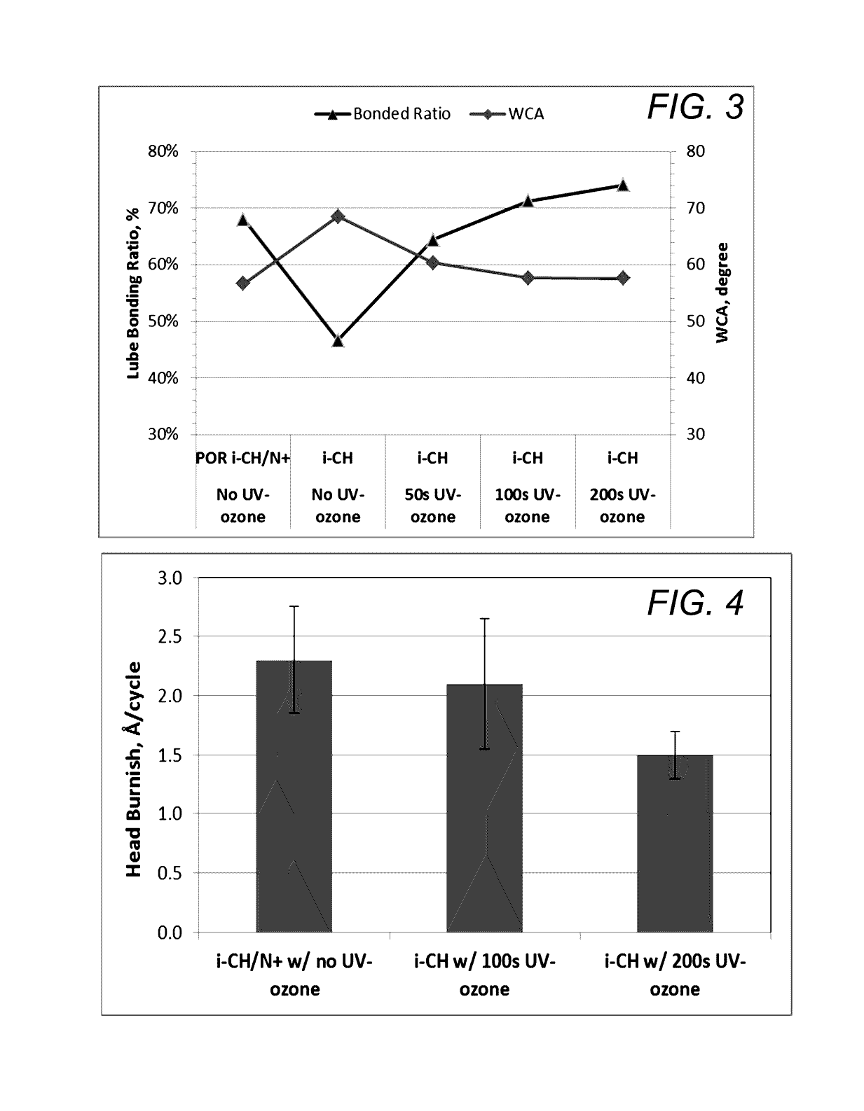

This also indicates that the carbon-hydrogen bonds at the surface were replaced with carbon-oxygen bonds. As a result, the surface energy increases, as indicated by the decrease in the WCA. The WCA and lube bonding ratio (in percentage) can be seen in FIG. 3. The lubricant bonding ratio increased and the water contact angle (WCA) decreased as the UV/ozone time increased. These results indicate that upon UV/ozone treatment, the i-CH surface becomes more hydrophilic and as a result, more lubricant can be bonded to the carbon surface.

The magnetic discs were subjected to head burnish testing. FIG. 4 shows the results thereof. The results show that the media with UV/ozone treatment had a reduced head burnish level. This indicates that surface treatment with UV/ozone improves the carbon-lubricant interactions at the interface and therefore improves the durability of the head-disk interface.

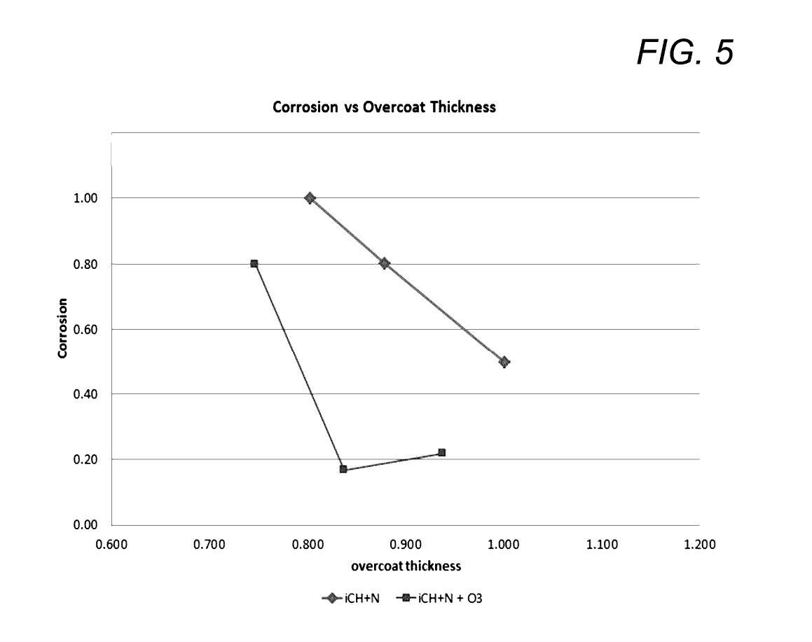

FIG. 5 shows corrosion resistance data from magnetic media coated with nitrogenated carbon overcoat and the same film after exposure to an ozone flux. Corrosion was monitored by determining the surface concentration of metal oxide type corrosion products on the media surface after a fixed exposure to hot/wet environmental conditions. As seen from FIG. 5, the oxygen treated film has significantly less corrosion products on its surface at all overcoat thicknesses compared to the surface without oxygenation.

In the preceding description, reference was made to the accompanying set of drawings that form a part hereof and in which are shown by way of illustration several specific embodiments. It is to be understood that other embodiments are contemplated and may be made without departing from the scope or spirit of the present disclosure. The preceding detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

“Include,” “including,” or like terms means encompassing but not limited to, that is, including and not exclusive. It should be noted that “top” and “bottom” (or other terms like “upper” and “lower”) are utilized strictly for relative descriptions and do not imply any overall orientation of the article in which the described element is located.

Thus, embodiments of methods of forming overcoats on magnetic storage media and magnetic storage media formed thereby are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation.

What is claimed is:

1. A method of forming a magnetic storage disc, the method comprising:
depositing a carbon containing material on a magnetic recording layer to form a carbon containing layer, wherein the carbon containing layer is deposited using chemical vapor deposition, ion beam deposition, or filtered cathodic arc deposition;
treating the carbon containing layer with a source of oxygen to form an oxygen layer; and
depositing a lubricant on the oxygen layer.

2. The method according to claim 1, wherein the carbon containing layer comprises carbon, hydrogen, nitrogen or a combination thereof.

3. The method according to claim 1, wherein the carbon containing layer comprises hydrogenated carbon, nitrogenated carbon, or a combination thereof.

4. The method according to claim 1, wherein the carbon containing layer is deposited using chemical vapor deposition.

5. The method according to claim 4, wherein the carbon containing layer is deposited using plasma enhanced chemical vapor deposition.

6. The method according to claim 1, wherein treating the carbon with a source of oxygen comprises UV exposure, ozone exposure, oxygen plasma, or a combination thereof.

7. The method according to claim 6, wherein treating the carbon with a source of oxygen comprises a combination of UV exposure and ozone.

8. The method according to claim 1, wherein the carbon containing layer is treated for about 1 second to about 5 minutes.

9. The method according to claim 1, wherein the carbon containing layer is treated for about 90 seconds to about 4 minutes.

10. A method of forming a magnetic storage disc, the method comprising:
depositing a carbon containing material on a magnetic recording layer to form a carbon-containing layer, wherein the carbon-containing layer is deposited using chemical vapor deposition, ion beam deposition, or filtered cathodic arc deposition;
forming an oxygen layer on the carbon-containing layer; and
depositing a lubricant on the oxygen layer.

11. The method according to claim 10, wherein the carbon-containing layer comprises carbon, hydrogen, nitrogen or a combination thereof.

12. The method according to claim 10, wherein the carbon-containing layer comprises amorphous carbon.

13. The method according to claim 10, wherein the carbon-containing layer is deposited using chemical vapor deposition.

14. The method according to claim 13, wherein the carbon-containing layer is deposited using plasma enhanced chemical vapor deposition.

15. The method according to claim 10, wherein forming the oxygen layer on the carbon-containing layer comprises UV exposure, ozone exposure, oxygen plasma, or a combination thereof.

16. The method according to claim 15, wherein forming the oxygen layer on the carbon-containing layer comprises a combination of UV exposure and ozone.

17. The method according to claim 10, wherein forming the oxygen layer on the carbon-containing layer takes about 1 second to about 5 minutes.

18. The method according to claim 10, wherein forming the oxygen layer on the carbon-containing layer takes about 90 seconds to about 4 minutes.

19. An article comprising:
a substrate;
a magnetic recording layer;
a protective carbon overcoat layer formed on the magnetic recording layer;
an oxygen layer formed on the protective carbon overcoat layer; and
a lubricant layer formed on the oxygen layer.

20. The article according to claim 19, wherein the oxygen layer comprises a monolayer of oxygen atoms bonded to carbon atoms of the protective carbon overcoat.
